(19) United States
(12) Patent Application Publication
(10) Pub. No.: US 2003/0193386 A1
(43) Pub. Date: Oct. 16, 2003

(54) Miniaturized common mode filter

(76) Inventors: Bin-Chyi Tseng, Chiayi City (TW); Jyh-Wen Sheen, Hsinchu (TW)

Correspondence Address: DELLETT AND WALTERS, 310 S.W. FOURTH AVENUE, SUITE 1101, PORTLAND, OR, 97204, US

(21) Appl. No.: 10/254,303

(22) Filed: Sep. 24, 2002

(30) Foreign Application Priority Data
Apr. 12, 2002 (TW) 091107427

(51) Int. Cl. H01F 5/00

(52) U.S. Cl. 336/200

(57) ABSTRACT

A miniaturized common mode filter is composed of multiple substrates with a positive coil and a negative coil formed on alternate substrates. The positive coils are sequentially connected via conductive through holes defined in each substrate, as are the negative coils. The pattern of each positive coil is interlaced with that of each negative coil, whereby when the positive and negative coils are alternately stacked, the positive coils do not overlap negative coils. With such an interlaced configuration of the coils, the problem of the parasitic capacitance is eliminated. Moreover, the thickness of each substrate can be decreased so the size of the entire filter is effectively reduced.

### BACKGROUND OF THE INVENTION

1. Field of the Invention

The present invention relates to a miniaturized common mode filter, and more particularly to a common mode filter with a greatly simplified design so that it can be manufactured very economically.

2. Description of Related Arts

With reference to FIG. 5, an early conventional common mode filter (50) is composed of a pair of coils (51, 52) wound around a magnetic core (53). Since the winding process of the coils (51, 52) is very complex and the size of the coils (51, 52) is difficult to reduce, the manufacturing cost of the filter (50) accordingly remains expensive and unfavorable to mass production.

Based on the great advances in the multi-layer circuit techniques, the volume of the common filter (50) can be effectively reduced. With reference to FIG. 6, a conventional common mode filter (60), fabricated with multi-layer circuit techniques, is mainly made up of multiple magnetic substrates (600-613), wherein positive coils (701-706) and negative coils (711-714) are alternately formed on each of the magnetic substrates (600-613). After the magnetic substrates (600-613) provided with opposite coils (701-706) and (711-714) are alternately arranged in a stack, the positive coils (701-706) are electrically and sequentially connected via through holes (not numbered) defined in each of the magnetic substrates (600-613), wherein the negative coils (711-714) are also connected in sequence in the same way.

Although the size of the common mode filter (60) implemented with the multi-layer process is much smaller than the early filter (50), the filter (60) still has some drawbacks that need to be solved.

As previously described, the positive coils (701-706) and negative coils (711-714) are correspondingly and alternately provided on the substrates (600-613). When two adjacent substrates (600-613) are stacked together, a segment of the positive coil (701-706) overlaps a segment of the negative coils (711-714). For example, when substrate (603) is stacked on substrate (604), a segment (denoted with A) of the negative coil (711) just overlaps above a segment (denoted with A′) of the positive coil (702). If the substrate (603) between the two coils segments (A, A′) is not thick enough, a parasitic capacitance will be generated between the overlapping segments (A, A′). The performance of the common mode filter (60) will be greatly influenced by the parasitic capacitance if the undesired virtual element occurs. Consequently, this serious problem accordingly should be overcome.

A known solution to overcome the parasitic capacitance is increasing the thickness of the substrates (600-613) or by narrowing the coils (701-706), (711-714). However, increasing the thickness is counterproductive to the miniaturization of the filter. In the alternate solution, the process to form the narrowed coils is difficult to perform.

With reference to FIGS. 7 and 8, another type of common mode filter (80) is shown. The common mode filter (80) is also composed of stacked laminated substrates (81-85). A first coil electrode (90) is deposited on a surface of an substrate (83), wherein the electrode (90) is connected at one end to a first external electrode (91) that is patterned together with the first coil electrode (90). The other end of the first coil electrode (90) is electrically connected to one end of a first lead electrode (200) through through-hole electrodes (100) defined in the substrates (83, 84).

A second coil electrode (95) formed as a spiral shape is provided on a surface of the substrate (84) and connected at one end to a second external electrode (96). The other end of the second coil electrode (95) is connected to one end of a second electrode (210) through the through-hole electrode (100) formed within the substrate (84).

As shown in FIG. 8, the first coil electrode (90) just overlaps above the second coil electrode (95) after all substrates (81-85) are stacked up to form a complete common mode filter (80). Certainly, the parasitic capacitance will be generated between the overlapping coils (90, 95).

To overcome the shortcomings, a miniaturized common mode filter in accordance with the present invention obviates or mitigates the aforementioned problems.

### SUMMARY OF THE INVENTION

The main objective of the present invention is to provide a miniaturized common mode filter that retains the required characteristic impedance of the differential mode signal, and is capable of avoiding the generation of parasitic capacitance without needing to increase the thickness of the substrates or to narrow the coils formed on the substrates.

To achieve the objective of the present invention, the common mode filter is composed of multiple substrates arranged in the form of a stack, negative coils and positive coils alternately formed on each of the substrates. The positive coils are electrically connected in sequence through holes defined in the substrates, as are the negative coils. Further, the characteristic of the present invention is that the positive coils layout and the negative coils layout, both respectively are provided on two stacked adjacent substrates, are interlaced and do not overlap each other. Thereby the parasitic capacitor is alleviated and the size of the common mode filter is effectively reduced.

The features and structure of the present invention will be more clearly understood when taken in conjunction with the accompanying figures.

### BRIEF DESCRIPTION OF THE DRAWINGS

FIG. 1 is an exploded perspective layer-by-layer view of a miniaturized common mode filter in accordance with the present invention;

FIG. 2 is an exploded perspective layer-by-layer view of the miniaturized common mode filter of FIG. 1 showing how to electrically connect each layer;

FIG. 3 is an exploded perspective view of adjacent layers in FIG. 1 showing a positive coil layout on a first substrate and a negative coil layout on a second substrate configured to form a non-overlapped pattern;

FIG. 4 is a cross-sectional side view of the common mode filter in FIG. 1;

FIG. 5 is a side view in partial section of an early conventional common mode filter;

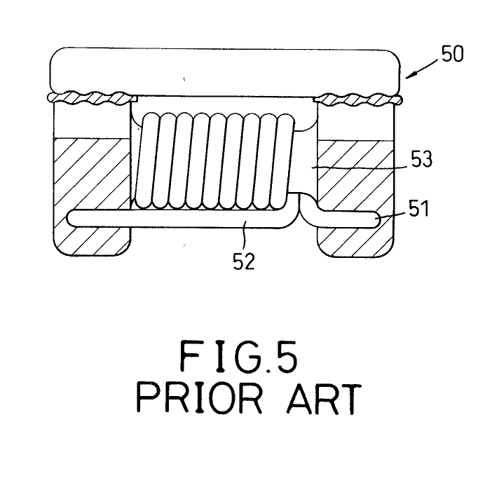

FIG. 6 is an exploded perspective layer-by-layer view of another conventional common mode filter;

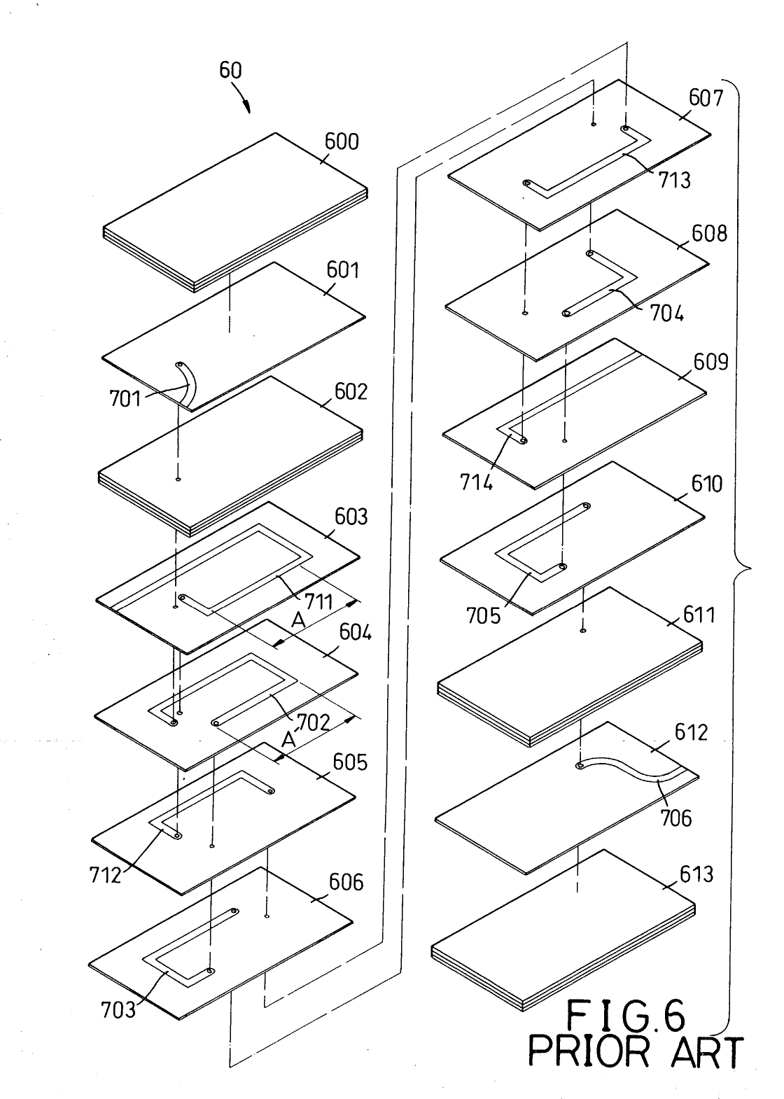

FIG. 7 is an exploded perspective layer-by-layer view of another conventional common mode filter; and

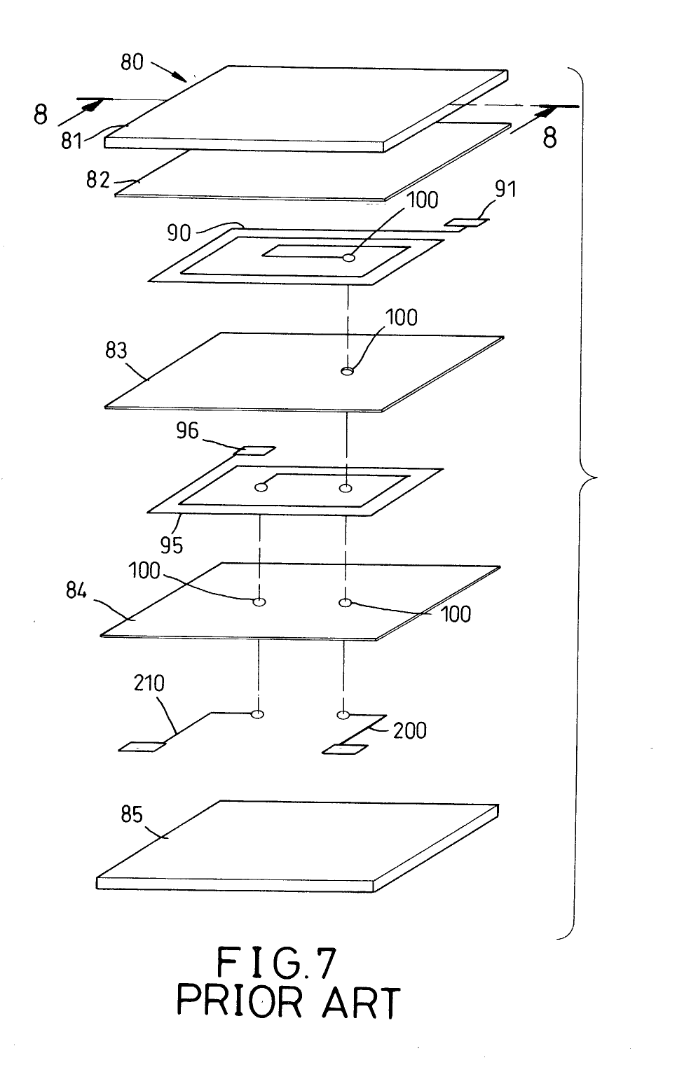

FIG. 8 is a cross-sectional side view of the conventional common mode filter shown in FIG. 7.

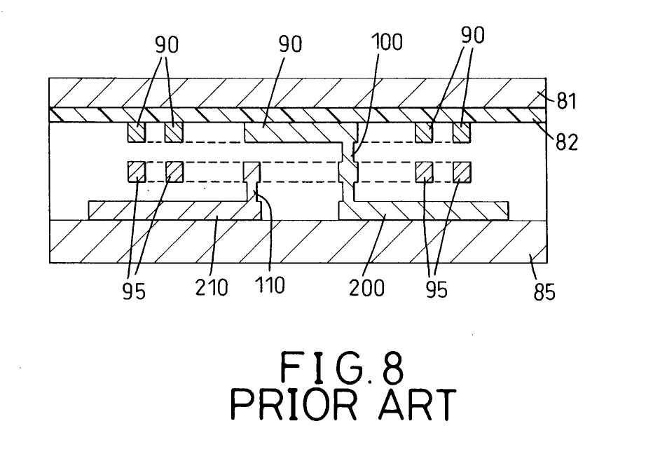

### DETAILED DESCRIPTION OF THE PREFERRED EMBODIMENT

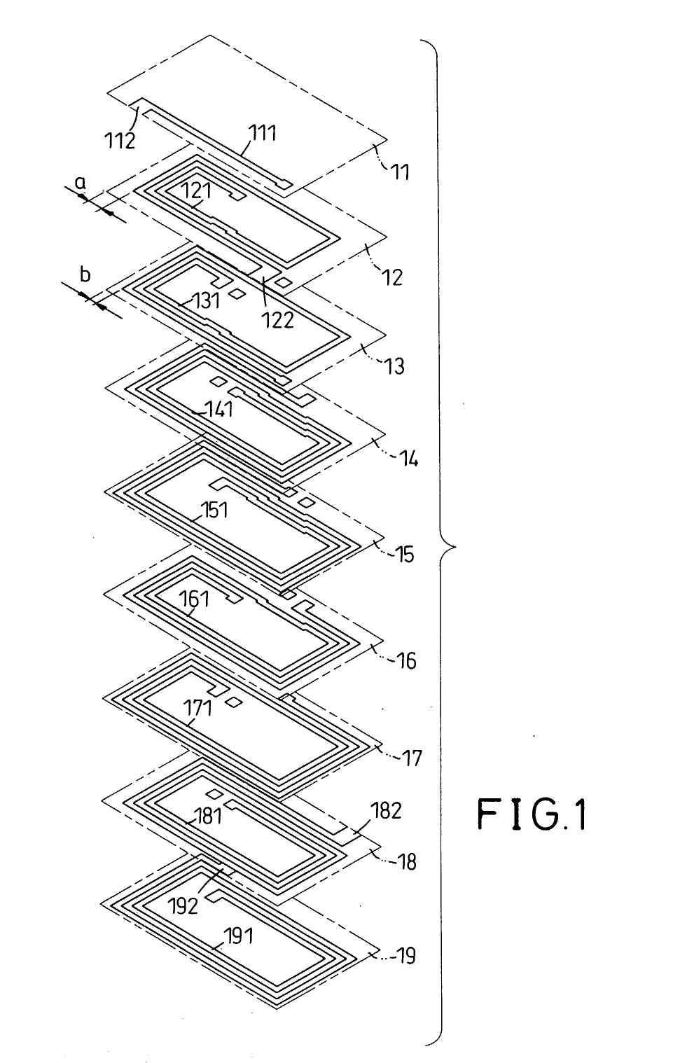

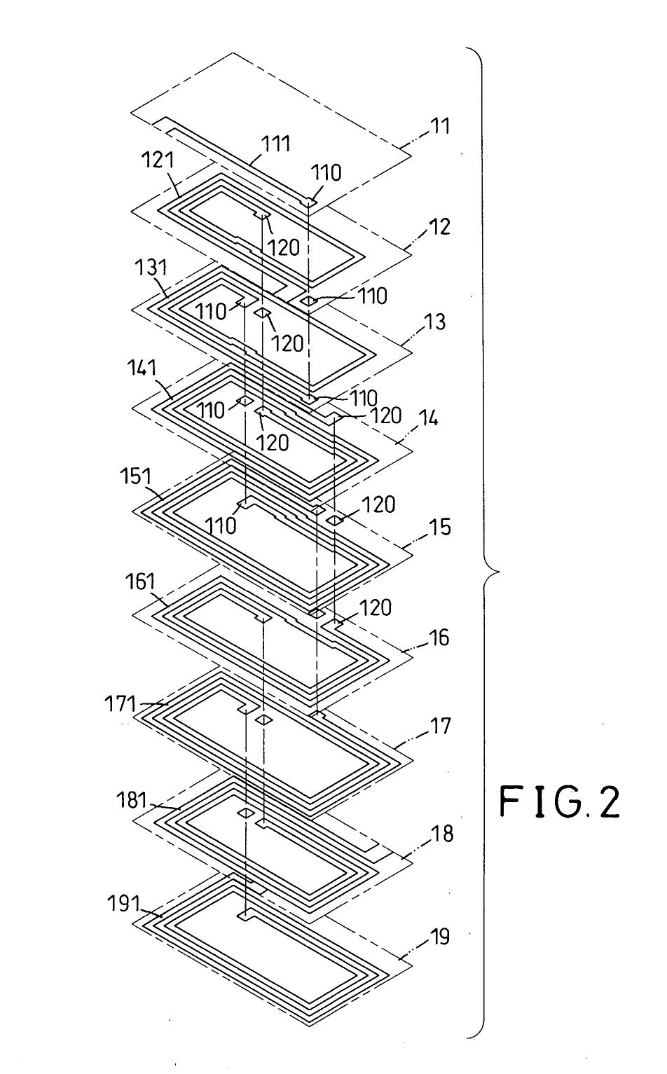

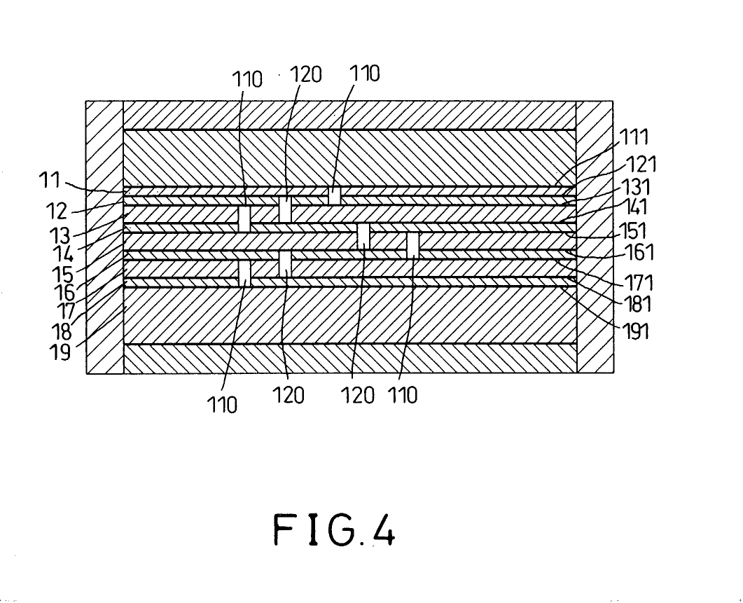

With reference to FIGS. 1 and 2, a common mode filter in accordance with the present invention comprises multiple substrates (11-19). Each substrates (11-19) is defined with conductive through holes (110, 120) and coil patterns (111-191). Positive coils (111, 131, 151, 171, 191) and negative coils (121, 141, 161, 181) are formed on alternate substrates (11-19). After all the substrates (11-19) are stacked, each positive coil (111, 131, 151, 171, 191) is able to connect in a sequence via the first plurality of through holes (110) (as shown in FIG. 4). Similarly the negative coils (121, 141, 161, 181) are connected as a sequence via the second plurality of through holes (120). In order to clearly represent the multi-layered configuration of the common mode filter, the thickness of each substrate (11-19) is omitted from the drawing.

Still with reference to FIG. 1, as an example, the common mode filter of the embodiment is made up of nine layers of substrates (11-19) that are sequentially designated with first to ninth substrates (11-19) hereinafter. The positive coils (111, 131, 151, 171, 191) are formed respectively on each of the odd-numbered substrate (11, 13, 15, 17, 19). Similarly, negative coils (121, 141, 161, 181) are formed respectively on each even-numbered substrate (12, 14, 16, and 18). On some of the multiple substrates, i.e. the first, second, eighth and ninth substrates (11, 12, 18 19), one end (112, 122, 182, 192) of each positive coil (111, 191) and each negative coil (121, 181) is used as an input/output terminal for connection to an external circuit (not shown).

The purpose of the present invention is to alleviate the parasitic capacitance while the positive coils (111, 131, 151, 171, 191) stack up the negative coils (121, 141, 161, 181) without increasing the thickness of each substrate (11-19). Moreover, the common mode filter of the present invention still retains good differential mode characteristic impedance to provide superior impedance-matching performance. For this objective, the layout of the positive coils (111, 131, 151, 171, 191) is purposely configured to interlace with the negative coils (121, 141, 161, 181).

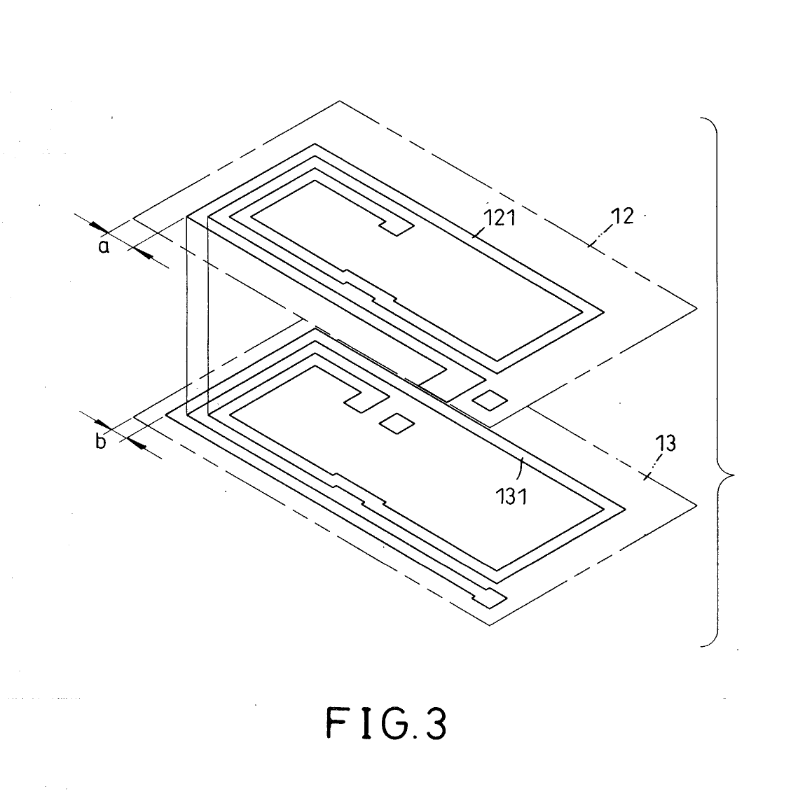

With reference to FIG. 3, the second substrate (12) and the third substrate (13) are shown as an example to explain the layout pattern of the coils on the substrate in detail. Both the negative coil (121) and positive coil (131) respectively on the second substrate (12) and the third substrate (13) are formed with a multi-turn spiral curve. A first distance between the edge of the second substrate (12) and the outer loop of the negative coil (121) is denoted with “a”. Similarly, a second distance between the edge of the third substrate (13) and the outer loop of the positive coil (131) is denoted with “b”, where the second distance “b” is narrower than the first distance “a”. Further, the outer loop of the negative coils (121) lies between two parallel lines forming the positive coil (131). Consequently, the pattern of the negative coil (121) is interlaced with the pattern of the positive coil (131) and does not overlap the positive coil (131). By using the foregoing configuration where positive coils (111, 131, 151, 171, 191) are prevented from overlapping adjacent negative coils (121, 141, 161, 181), the problem of the parasitic capacitance is accordingly overcome.

The pattern of each positive coil (111, 131, 151, 171, 191) formed on each odd-numbered substrate (11, 13, 15, 17, 19) is identical, and so are the negative coils (121, 141, 161, 181). Therefore, the mass production of the filter is efficient.

With reference to FIG. 4, because the parasitic capacitance is alleviated by properly configuring the pattern of the two opposite coils (111-191), not by increasing the thickness of the substrates (11-19), the thin substrate is capable of reducing the total thickness of the filter to satisfy the filter miniaturization requirement.

The foregoing description of the preferred embodiments of the present invention is intended to be illustrative only and, under no circumstances, should the scope of the present invention be restricted by the description of the specific embodiment.

What is claimed is:

1. A miniaturized common mode filter comprising multiple stacked substrates on each of which positive coils and negative coils are alternately formed, the positive coils are further connected in a sequence through a first plurality of conductive holes defined on each substrate, and the negative coils are further connected in a sequence through a second plurality of conductive holes defined on each substrate,
wherein the positive coil formed on one of the multiple substrates is interlaced with the negative coils formed on adjacent substrates, whereby the positive coil and the negative coil respectively formed on adjacent substrates are prevented from overlapping with each other.

2. The miniaturized common mode filter as claimed in claim 1, wherein the positive coils and the negative coils formed on a part of the multiple stacked substrates have at least one end used as an input/output terminal.

3. The miniaturized common mode filter as claimed in claim 1, wherein each positive coil and each negative coil are formed substantially in a spiral shape.
